(19) United States
(12) Patent Application Publication
(10) Pub. No.: US 2025/0221265 A1
(43) Pub. Date: Jul. 3, 2025

(54) DISPLAY DEVICE AND ELECTRONIC DEVICE INCLUDING THE SAME

(71) Applicant: Samsung Display Co., LTD., Yongin-si (KR)

(72) Inventors: YONGIL KIM, Yongin-si (KR); YOUNGGYU JUNG, Yongin-si (KR); JAEHOON LEE, Yongin-si (KR); JUNPYO LEE, Yongin-si (KR)

(21) Appl. No.: 18/946,767

(22) Filed: Nov. 13, 2024

(30) Foreign Application Priority Data
Dec. 28, 2023 (KR) 10-2023-0194379

(51) Int. Cl. H10K 59/80; H10K 102/00

(52) U.S. Cl. CPC H10K 59/873; H10K 59/8792; H10K 2102/351

(57) ABSTRACT

A display device according to one or more embodiments may include a display panel including a substrate having a display area and a non-display area, pixels in the display area above the substrate, and an encapsulation layer covering the pixels, a panel bottom member under the substrate, including a metal layer, and exposing an edge portion of the substrate, and a coating layer under the edge portion of the substrate, and surrounding at least a portion of the panel bottom member.

### CROSS-REFERENCE TO RELATED APPLICATION(S)

The present application claims priority to, and the benefit of, Korean Patent Application No. 10-2023-0194379, filed on Dec. 28, 2023, in the Korean Intellectual Property Office, the entire disclosure of which is incorporated herein by reference.

### BACKGROUND

### 1. Field

Embodiments relate to a display device, and to an electronic device including the same.

### 2. Description of the Related Art

Flat panel display devices are replacing cathode ray tube display devices due to their lightweight and thin characteristics. As representative examples of such flat panel display devices, there are liquid crystal display devices and organic light-emitting diode display devices.

The display device may be assembled with a bracket, chassis, or the like to form an electronic device. When assembling the display device with the bracket, the chassis, or the like, a tensile stress or an impact may be applied to a substrate of the display device, such that the substrate may be damaged.

### SUMMARY

Embodiments provide a display device with improved reliability. Embodiments also provide an electronic device with improved reliability.

Additional aspects of the present disclosure will be set forth in the description which follows, and in part will be apparent from the description, or may be learned by practice of embodiments of the present disclosure.

A display device according to one or more embodiments may include a display panel including a substrate having a display area and a non-display area, pixels in the display area above the substrate, and an encapsulation layer covering the pixels, a panel bottom member under the substrate, including a metal layer, and exposing an edge portion of the substrate, and a coating layer under the edge portion of the substrate, and surrounding at least a portion of the panel bottom member.

The coating layer may include a polymer resin.

The coating layer may include a glass frit.

A thickness of the coating layer may be less than or equal to a thickness of the panel bottom member.

The coating layer may be spaced apart from the panel bottom member.

The coating layer may adjoin the panel bottom member.

The edge portion of the substrate may include a first edge portion extending in a first direction, a second edge portion parallel to the first edge portion, a third edge portion extending in a second direction crossing the first direction, and a fourth edge portion parallel to the third edge portion, wherein the display device further includes a connection film including a first end portion connected on the first edge portion of the substrate, and a second end portion opposite the first end portion, the connection film being bent so that the second end portion is under the substrate, and a circuit board under the substrate, and connected to the second end portion.

The coating layer may be under the first edge portion, the second edge portion, the third edge portion, and the fourth edge portion of the substrate.

The coating layer may have a ring shape in a plan view.

The coating layer may be under the second edge portion, the third edge portion, and the fourth edge portion of the substrate, and is not under the first edge portion of the substrate.

The display device may further include a black printing layer under the substrate, wherein the panel bottom member and the coating layer are under the black printing layer.

The display device may further include a polarizer above the display panel.

The panel bottom member may further include an impact-absorbing layer between the substrate and the metal layer.

A display device according to one or more embodiments may include a display panel including a substrate having a display area and a non-display area, pixels in the display area above the substrate, an encapsulation layer covering the pixels, and a panel bottom member under the substrate, including a metal layer, and having an area that is greater than an area of the substrate, the substrate exposing an edge portion of the panel bottom member.

Edges of the substrate may be inside edges of the panel bottom member in a plan view.

An electronic device according to one or more embodiments may include a display panel including a substrate having a display area and a non-display area, pixels in the display area above the substrate, an encapsulation layer covering the pixels, a panel bottom member under the substrate to expose an edge portion of the substrate, and including a metal layer, a coating layer under the edge portion of the substrate to surround at least a portion of the panel bottom member, a bracket attached under the panel bottom member, and covering edges of the display panel and the panel bottom member, a top chassis attached on the display panel, and a bottom chassis attached under the bracket and connected to the top chassis.

The coating layer may include a polymer resin.

The coating layer may include a glass frit.

A thickness of the coating layer may be less than or equal to a thickness of the panel bottom member.

The coating layer may have a ring shape in a plan view.

The display device according to embodiments may include the coating layer located under the substrate and covering the edge portion of the substrate. The coating layer can prevent or reduce development of micro cracks from the edge portion of the substrate when manufacturing the electronic device by assembling the display device with the bracket, the chassis, or the like. Thus, the reliability of the display device and the electronic device can be improved.

It is to be understood that both the foregoing general description and the following detailed description are exemplary and explanatory and are intended to provide further explanation of the present disclosure.

### BRIEF DESCRIPTION OF THE DRAWINGS

The accompanying drawings, which are included to provide a further understanding of the present disclosure and are incorporated in and constitute a part of this specification, illustrate embodiments of the present disclosure, and together with the description serve to explain the present disclosure.

FIGS. 1A and 1B are plan views illustrating a display device according to one or more embodiments.

FIGS. 2A and 2B are bottom views illustrating the display device according to one or more embodiments.

FIG. 3 is a cross-sectional view illustrating the display device according to one or more embodiments.

FIG. 4 is an enlarged cross-sectional view of area A of FIG. 3.

FIGS. 5A and 5B are bottom views illustrating another example of the display device according to one or more embodiments.

FIG. 6 is a diagram illustrating an electronic device including the display device of FIG. 3.

FIG. 7 is a cross-sectional view illustrating a display device according to one or more other embodiments.

FIG. 8 is a diagram illustrating an electronic device including the display device of FIG. 7.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

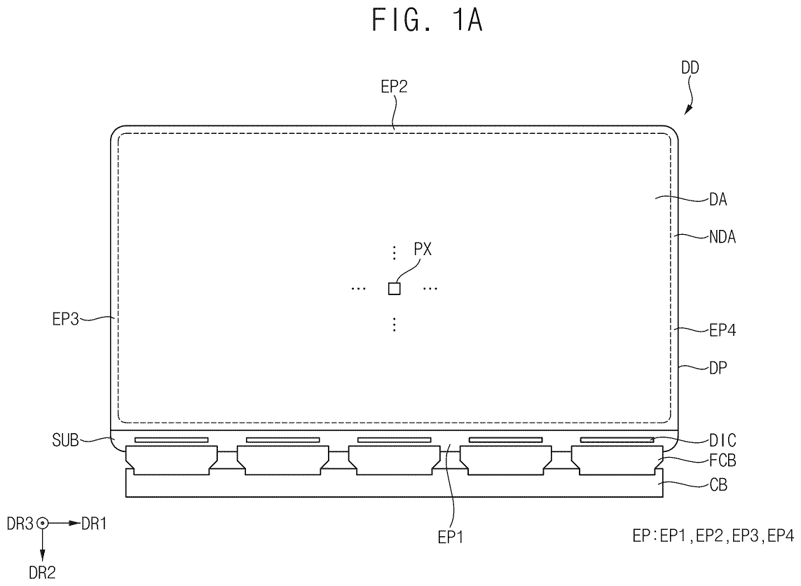

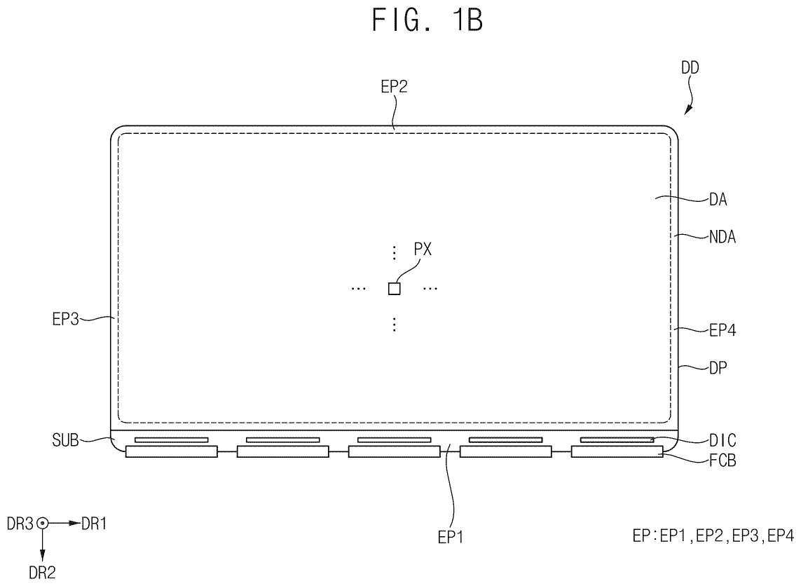

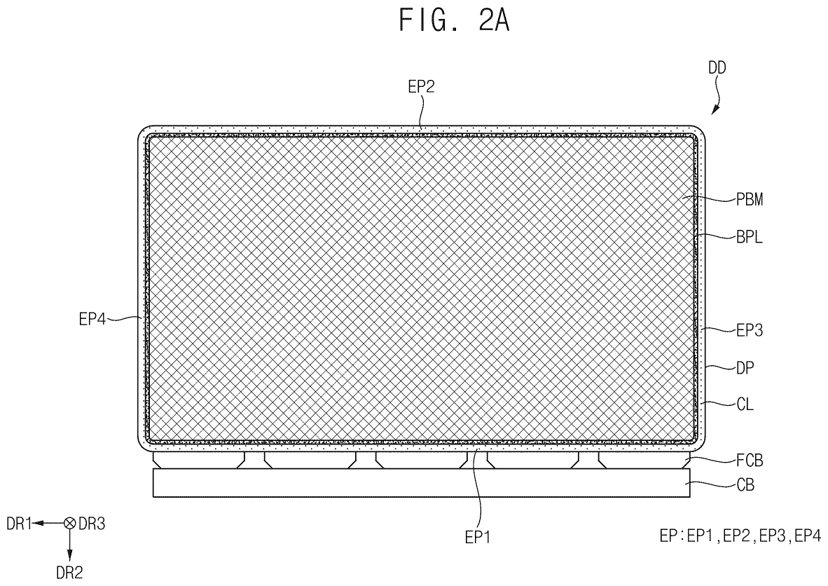

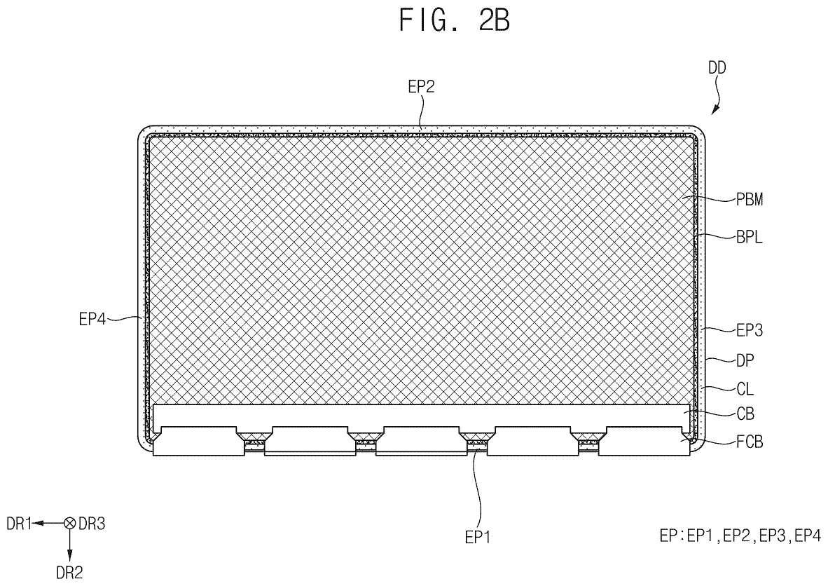

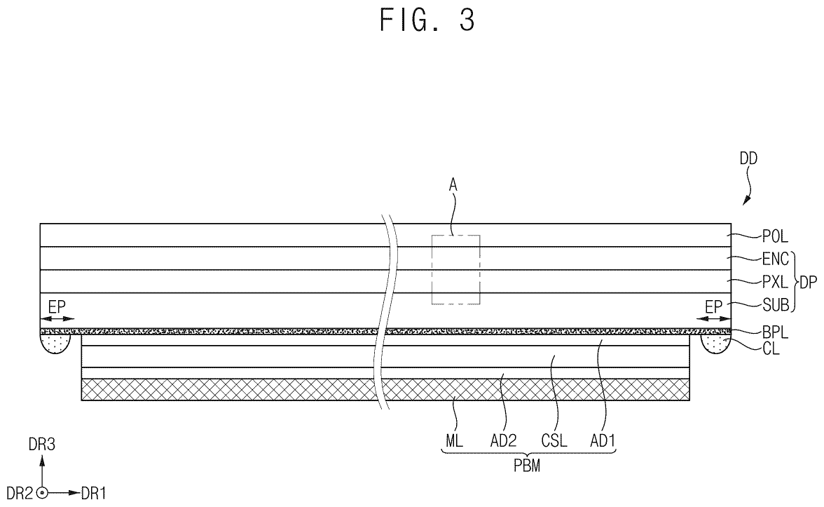

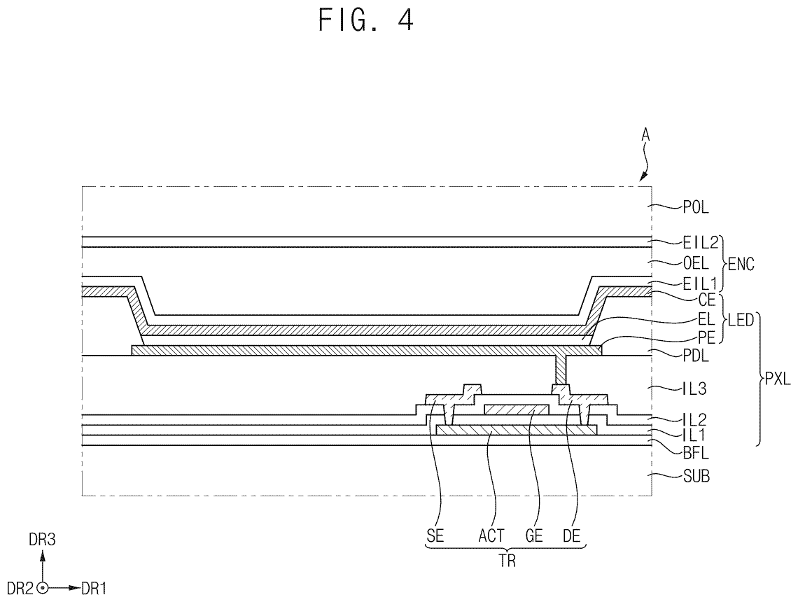

FIGS. 1A and 1B are plan views illustrating a display device according to one or more embodiments. FIGS. 2A and 2B are bottom views illustrating the display device according to one or more embodiments. FIG. 3 is a cross-sectional view illustrating the display device according to one or more embodiments. FIG. 4 is an enlarged cross-sectional view of area A of FIG. 3.

FIGS. 1A and 2A may illustrate a state in which a flexible circuit film FCB included in the display device DD is not bent, and FIGS. 1B and 2B may illustrate a state in which the flexible circuit film FCB is bent.

Referring to FIGS. 1A to 4, the display device DD according to one or more embodiments may have a display surface defined by a first direction DR1, and a second direction DR2 crossing the first direction DR1. The display device DD may display an image in a third direction DR3 through the display surface. The third direction DR3 may be substantially parallel to a normal direction of the display surface. The display surface may correspond to an upper surface (or a front surface) of the display device DD.

In one or more embodiments, the display device DD may include a display panel DP, a driving chip DIC, the flexible circuit film FCB, a circuit board CB, a polarizer POL (see FIG. 3), a panel bottom member PBM, and a coating layer CL.

The display panel DP may have a display area DA and a non-display area NDA. A plurality of pixels PX for generating the image may be located in the display area DA. For example, the pixels PX may be located in a matrix form along the first direction DR1 and the second direction DR2.

Each of the pixels PX may include a pixel circuit and a light-emitting element LED. The pixel circuit may include at least one thin film transistor TR and at least one capacitor. The thin film transistor TR may generate a driving current, and may provide the generated driving current to the light-emitting element LED. The light-emitting element LED may emit light based on the driving current. For example, the light-emitting element LED may include an organic light-emitting diode, an inorganic light-emitting diode, a quantum dot light-emitting diode, a micro light-emitting diode, or the like. The image may be generated by combining light emitted from each of the pixels PX.

The non-display area NDA may be located outside the display area DA. For example, the non-display area NDA may surround the display area DA in a plan view.

The display panel DP may include a substrate SUB having the display area DA and the non-display area NDA, a pixel layer PXL on the substrate SUB, and an encapsulation layer ENC on the pixel layer PXL (as used herein, “on” may mean “above”).

The substrate SUB may be an insulating substrate including or formed of a transparent material or a non-transparent material. In one or more embodiments, the substrate SUB may be a rigid substrate including a material, such as glass or quartz. In one or more other embodiments, the substrate SUB may be a flexible substrate including plastic.

The substrate SUB may include a central portion, and an edge portion EP located outside the central portion. The edge portion EP may be defined as a portion that is inward from edges of the substrate SUB, and that has a width (e.g., predetermined width) in a plan view.

In one or more embodiments, as illustrated in the drawing, the substrate SUB may have an overall rectangular shape in a plan view. In this case, the edge portion EP of the substrate SUB may include a first edge portion EP1 extending in the first direction DR1, a second edge portion EP2 parallel to the first edge portion EP1, a third edge portion EP3 extending in the second direction DR2, and a fourth edge portion EP4 parallel to the third edge portion EP3.

A buffer layer BFL may be located on the substrate SUB (as used herein, “located on” may mean “above”). The buffer layer BFL may prevent or reduce penetration of impurities, such as oxygen or moisture, into an upper portion of the substrate SUB through the substrate SUB. The buffer layer BFL may include an inorganic material. In one or more embodiments, for example, the buffer layer BFL may include silicon oxide (SiO), silicon nitride (SiN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), titanium oxide (TiO), or the like. These can be used alone or in a combination thereof. The buffer layer BFL may have a single-layered structure, or a multi-layered structure including a plurality of insulating layers. In one or more embodiments, the buffer layer BFL may be omitted.

The pixel layer PXL may be located on the buffer layer BFL. The pixel layer PXL may include the pixel circuit and the light-emitting element LED. The pixel circuit may include at least one thin film transistor TR and may include the capacitor. The thin film transistor TR may include an active layer ACT, a gate electrode GE, a source electrode SE, and a drain electrode DE.

The active layer ACT may be located on the buffer layer BFL. The active layer ACT may include an oxide semiconductor, a silicon semiconductor, an organic semiconductor, or the like. In one or more embodiments, for example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), or zinc (Zn). The silicon semiconductor may include an amorphous silicon, a polycrystalline silicon, or the like. The active layer ACT may include a source area, a drain area, and a channel area positioned between the source area and the drain area.

A first insulating layer IL1 may be located on the active layer ACT. The first insulating layer IL1 may cover the active layer ACT on the buffer layer BFL. The first insulating layer IL1 may include an inorganic insulating material.

The gate electrode GE may be located on the first insulating layer IL1. The gate electrode GE may overlap the channel area of the active layer ACT. The gate electrode GE may include a conductive material, such as a metal, an alloy, a conductive metal nitride, a conductive metal oxide, a transparent conductive material, or the like. In one or more embodiments, for example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), or the like. These can be used alone or in a combination thereof. The gate electrode GE may have a single-layered structure, or a multi-layered structure including a plurality of conductive layers.

A second insulating layer IL2 may be located on the gate electrode GE. The second insulating layer IL2 may cover the gate electrode GE on the first insulating layer IL1. The second insulating layer IL2 may include an inorganic insulating material.

The source electrode SE and the drain electrode DE may be located on the second insulating layer IL2. The source electrode SE and the drain electrode DE may be connected to the source area and the drain area of the active layer ACT, respectively. Each of the source electrode SE and the drain electrode DE may include a conductive material.

A third insulating layer IL3 may be located on the source electrode SE and the drain electrode DE. The third insulating layer IL3 may include an organic insulating material. In one or more embodiments, for example, the third insulating layer IL3 may include photoresist, polyacryl-based resin, polyimide-based resin, polyamide-based resin, siloxane-based resin, acryl-based resin, epoxy-based resin, or the like. These can be used alone or in a combination thereof.

A pixel electrode PE may be located on the third insulating layer IL3. The pixel electrode PE may include a conductive material. The pixel electrode PE may have a single-layered structure, or a multi-layered structure including a plurality of conductive layers. The pixel electrode PE may be connected to the drain electrode DE through a contact hole formed in the third insulating layer IL3. Accordingly, the pixel electrode PE may be electrically connected to the thin film transistor TR.

A pixel-defining layer PDL may be located on the pixel electrode PE. The pixel-defining layer PDL may cover a peripheral portion of the pixel electrode PE, and may define a pixel opening exposing a central portion of the pixel electrode PE. The pixel-defining layer PDL may include an organic insulating material.

An emission layer EL may be located on the pixel electrode PE. The emission layer EL may be located in the pixel opening of the pixel-defining layer PDL. In some embodiments, the emission layer EL may include at least one of an organic light-emitting material or quantum dot.

In one or more embodiments, the organic light-emitting material may include a low molecular organic compound or a high molecular organic compound. Examples of the low molecular organic compound may include copper phthalocyanine, N,N′-diphenylbenzidine, tris-(8-hydroxyquinoline)aluminum, or the like. Examples of the high molecular organic compound may include poly(3,4-ethylenedioxythiophene), polyaniline, poly-phenylenevinylene, polyfluorene, or the like. These can be used alone or in a combination thereof.

In one or more embodiments, the quantum dot may include a core including a Group II-VI compound, a Group III-V compound, a Group IV-VI compound, a Group IV element, and/or a Group IV compound. In one or more embodiments, the quantum dot may have a core-shell structure including the core, and a shell surrounding the core. The shell may serve as a protection layer for reducing or preventing chemical denaturing of the core to maintain semiconductor characteristics, and may serve as a charging layer for imparting electrophoretic characteristics to the quantum dot.

A common electrode CE may be located on the emission layer EL. The common electrode CE may also be located on the pixel-defining layer PDL. The common electrode CE may include a conductive material. The pixel electrode PE, the emission layer EL, and the common electrode CE may form the light-emitting element LED. The light-emitting element LED may further include various functional layers (e.g., a hole injection layer, a hole transport layer, an electron transport layer, an electron injection layer, or the like) located between the pixel electrode PE and the emission layer EL, or between the emission layer EL and the common electrode CE.

The encapsulation layer ENC may be located on the common electrode CE. The encapsulation layer ENC may include at least one inorganic encapsulation layer and at least one organic encapsulation layer. In one or more embodiments, the encapsulation layer ENC may include a first inorganic encapsulation layer EIL1 located on the common electrode CE, an organic encapsulation layer OEL located on the first inorganic encapsulation layer EIL1, and a second inorganic encapsulation layer EIL2 located on the organic encapsulation layer OEL, but this is only an example and embodiments are not limited thereto. The organic encapsulation layer OEL may cover the entire display area DA. In addition, in one or more embodiments, the display panel DP may further include various functional layers (e.g., a touch-sensing layer, a color filter layer, a light-collecting layer, or the like) located on the encapsulation layer ENC.

The driving chip DIC may be located in the non-display area NDA on the substrate SUB. The driving chip DIC may be located on the first edge portion EP1 of the substrate SUB. For example, the driving chip DIC may be directly mounted on the display panel DP in a chip-on-glass (COG) manner, but this is only an example and embodiments are not limited thereto. For another example, the driving chip DIC may be mounted on the flexible circuit film FCB or the circuit board CB.

A first end portion of the flexible circuit film FCB may be connected to the non-display area NDA on the substrate SUB. The first end portion of the flexible circuit film FCB may be connected at the first edge portion EP1 of the substrate SUB. The circuit board CB may be connected to a second end portion of the flexible circuit film FCB opposite to the first end portion. As illustrated in FIGS. 1B and 2B, the flexible circuit film FCB may be bent so that the second end portion of the flexible circuit film FCB and the circuit board CB connected thereto may be located under the substrate SUB. For example, as the flexible circuit film FCB is bent, the circuit board CB may be located under the panel bottom member PBM.

The driving chip DIC and the circuit board CB may be electrically connected to the display panel DP. The driving chip DIC and circuit board CB may provide driving signals to the display panel DP. The driving signal may be various signals for driving the display panel DP, such as a driving voltage, a gate signal, a data signal, or the like. The driving signal may be transferred to the pixels PX located in the display area DA through a plurality of pads and a plurality of transfer lines.

The polarizer POL may be located on the display panel DP. The polarizer POL may be located on the encapsulation layer ENC. The polarizer POL may reduce reflection of light incident from outside. That is, the polarizer POL may reduce external light reflectance of the display device DD.

In one or more embodiments, the display device DD may further include a cover window located on the polarizer POL and having light transmittance. In one or more other embodiments, the cover window may be omitted.

In one or more embodiments, the display device DD may further include a black printing layer BPL located under the substrate SUB. The black printing layer BPL 1 may be formed by printing black ink on a lower surface of the substrate SUB. The black printing layer BPL may block light. The black printing layer BPL can absorb incident light, and may reduce or prevent visibility of various components, which may be located under the substrate SUB, as viewed from the top of the display device DD.

In one or more other embodiments, the black printing layer BPL may be omitted. The panel bottom member PBM may be located under the display panel DP. The panel bottom member PBM may be located under the substrate SUB. The panel bottom member PBM may be attached on a lower surface of the black printing layer BPL. When the black printing layer BPL is omitted, the panel bottom member PBM may be attached on the lower surface of the substrate SUB. The panel bottom member PBM may cover the display area DA of the display panel DP. The panel bottom member PBM may further cover a portion of the non-display area NDA of the display panel DP.

An area of the panel bottom member PBM may be less than an area of the substrate SUB. The panel bottom member PBM may be located under the central portion of the substrate SUB, and may not be located under the edge portion EP of the substrate SUB. That is, the panel bottom member PBM may be located under the substrate SUB to expose the edge portion EP of the substrate SUB. In a plan view, the edges of the substrate SUB may be located outside edges of the panel bottom member PBM (e.g., in plan view).

The panel bottom member PBM may protect the display panel DP from an external environment under the display panel DP (e.g., impact, electromagnetic waves, noise, or the like). In addition, the panel bottom member PBM may diffuse heat generated in the display panel DP, and may reduce or prevent heat transfer to the display panel DP otherwise due to heat generated from electronic components, such as a processor, a battery, a memory, or the like, which may be located under the display panel DP in an electronic device.

In one or more embodiments, the panel bottom member PBM may include a first adhesive layer AD1, an impact-absorbing layer CSL, a second adhesive layer AD2, and a metal layer ML. The first adhesive layer AD1, the impact-absorbing layer CSL, the second adhesive layer AD2, and the metal layer ML may be stacked along the third direction DR3.

The first adhesive layer AD1 may attach the impact-absorbing layer CSL to the display panel DP. The impact-absorbing layer CSL may protect the display panel DP from impact applied from under the bottom member PBM. For example, the impact-absorbing layer CSL may be a porous layer formed of a material, such as polyurethane, polyethylene, or the like. The impact-absorbing layer CSL may include foam resin or elastomer. In one or more embodiments, the impact-absorbing layer CSL may be omitted. In this case, it is possible to reduce or prevent deformation of the substrate SUB due to compression of the impact-absorbing layer CSL.

The second adhesive layer AD2 may attach the impact-absorbing layer CSL and the metal layer ML to each other. The metal layer ML may dissipate heat generated from the electronic components, such as the processor, the battery, the memory, or the like. In addition, the metal layer ML may prevent or reduce electromagnetic waves, static electricity, noise, or the like from flowing from under the panel bottom member PBM to the display panel DP. The metal layer ML may include a metal having excellent thermal conductivity along with shield performance, such as copper, aluminum, or the like.

The coating layer CL may be located under the display panel DP. The coating layer CL may be located under the substrate SUB. The coating layer CL may be located on (e.g., below) the lower surface of the black printing layer BPL. When the black printing layer BPL is omitted, the coating layer CL may be located on (e.g., below) the lower surface of the substrate SUB. The coating layer CL may be located on the same layer as the panel bottom member PBM.

The coating layer CL may be located under the edge portion EP of the substrate SUB. In one or more embodiments, a thickness of the coating layer CL may be less than or equal to a thickness of the panel bottom member PBM. In one or more other embodiments, the thickness of the coating layer CL may be greater than the thickness of the panel bottom member PBM.

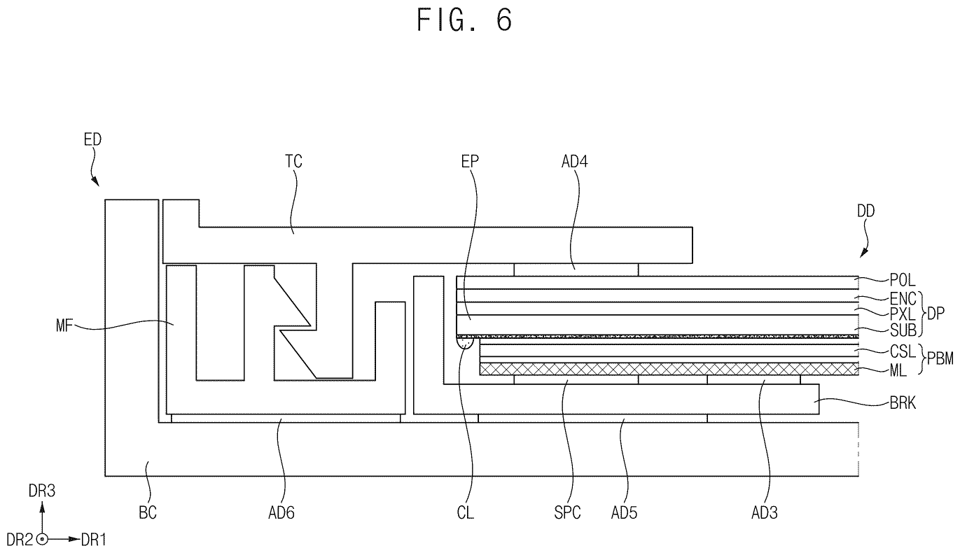

The coating layer CL may protect the edge portion EP of the substrate SUB. During the manufacturing process of the display panel DP, micro cracks may occur on the surface of the substrate SUB. For example, during the processing of the substrate SUB, the micro cracks may primarily occur in the edge portion EP of the substrate SUB. The coating layer CL may cover the edge portion EP of the substrate SUB where the micro cracks occur. In addition, a stiffness of the edge portion EP of the substrate SUB may be improved by the coating layer CL having a thickness (e.g., predetermined thickness), and a neutral surface of the edge portion EP of the display device DD may be close to the surface of the substrate SUB where the micro cracks occur. Accordingly, when manufacturing the electronic device by assembling the display device DD with a bracket, chassis, or the like, it is possible to prevent or reduce development of the micro cracks from the edge portion EP of the substrate SUB. Accordingly, reliability of the display device DD and the electronic device can be improved. This will be described in more detail later with reference to FIG. 6.

In one or more embodiments, the coating layer CL may include a polymer resin or a glass frit. For example, the coating layer CL may be formed by applying polymer resin or glass frit under the edge portion EP of the substrate SUB, and by then curing it with heat, ultraviolet rays, infrared rays, a laser, or the like. For example, the coating layer CL may be formed before the panel bottom member PBM is attached under the display panel DP. For another example, the coating layer CL may be formed after the panel bottom member PBM is attached under the display panel DP.

The coating layer CL may surround at least a portion of the panel bottom member PBM in a plan view. In one or more embodiments, as illustrated in FIGS. 2A and 2B, the coating layer CL may entirely surround the panel bottom member PBM in a plan view. The coating layer CL may be located under the first to fourth edge portions EP1, EP2, EP3, and EP4 of the substrate SUB. For example, the coating layer CL may have a ring shape in a plan view.

In one or more embodiments, as illustrated in FIGS. 2A and 2B, the coating layer CL may be spaced apart from the panel bottom member PBM. That is, in a plan view, the coating layer CL may be spaced apart from the panel bottom member PBM, and may surround the panel bottom member PBM. In one or more other embodiments, the coating layer CL may adjoin the panel bottom member PBM.

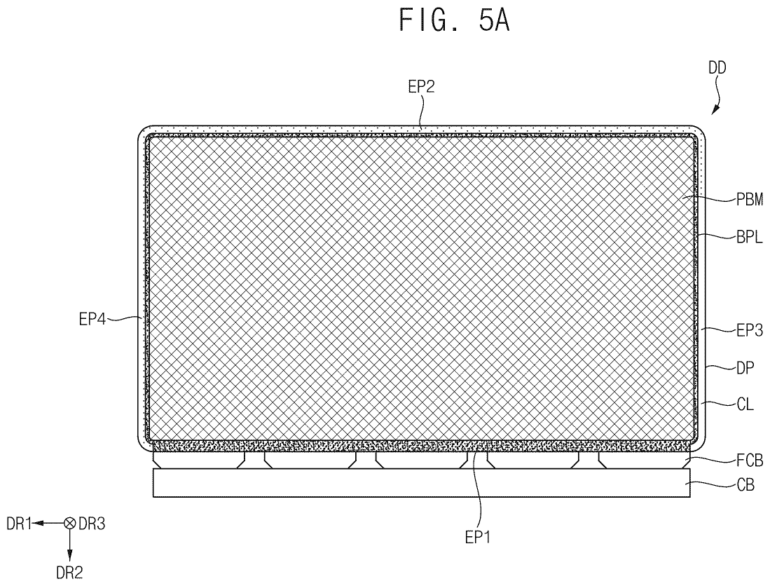

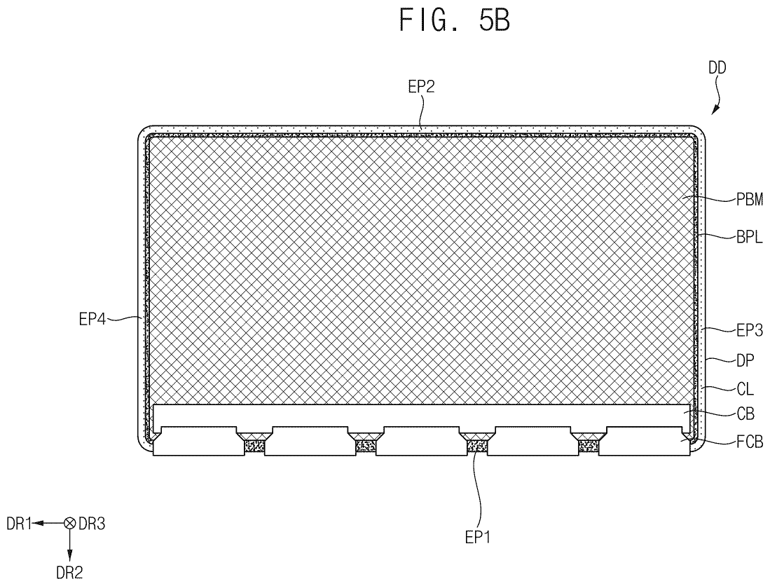

FIGS. 5A and 5B are bottom views illustrating another example of the display device according to one or more embodiments.

In one or more embodiments, as illustrated in FIGS. 5A and 5B, the coating layer CL may surround only a portion (e.g., three sides among four sides) of the panel bottom member PBM. For example, the coating layer CL may be located under the second to fourth edge portions EP2, EP3, and EP4 of the substrate SUB, and may not be located under the first edge portion EP1 of the substrate SUB to which the flexible circuit film FCB is connected. For example, the coating layer CL may have a ‘Π’ shape in a plan view.

FIG. 6 is a diagram illustrating an electronic device including the display device of FIG. 3.

Referring to FIG. 6, an electronic device ED according to one or more embodiments may include a display device DD, a bracket BRK, a top chassis TC, a bottom chassis BC, and a middle frame MF. The display device DD may be the display device DD described with reference to FIGS. 1A to 5B. Hereinafter, repeated descriptions may be omitted or simplified.

The bracket BRK may cover edges of the display device DD. For example, the bracket BRK may cover side surfaces of the display device DD, and may further cover edge portions of a lower surface (or a rear surface) of the display device DD. The display device DD may be attached to the bracket BRK by a third adhesive layer AD3. The third adhesive layer AD3 may attach the metal layer ML and the bracket BRK to each other. An upper surface of the third adhesive layer AD3 may contact the metal layer ML, and a lower surface of the third adhesive layer AD3 may contact the bracket BRK. The third adhesive layer AD3 may be a double-sided adhesive tape that has adhesive properties on both the upper and lower surfaces. In one or more embodiments, a spacer SPC for maintaining a gap (e.g., predetermined gap) may be located between the metal layer ML and the bracket BRK.

The top chassis TC may form a top (or front) edge of the electronic device ED. A fourth adhesive layer AD4 may be located between the top chassis TC and the display device DD. An upper surface of the fourth adhesive layer AD4 may contact the top chassis TC, and a lower surface of the fourth adhesive layer AD4 may contact the polarizer POL. For example, the fourth adhesive layer AD4 may be a double-sided adhesive tape that has adhesive properties on both the upper and lower surfaces. For another example, the fourth adhesive layer AD4 may be a single-sided adhesive tape that has adhesive properties only on the upper surface, and that does not have adhesive properties on the lower surface.

The bottom chassis BC may form a side edge of the electronic device ED, and may cover the lower surface (or the rear surface) of the display device DD. The bottom chassis BC may be attached to the bracket BRK by a fifth adhesive layer AD5.

The middle frame MF may connect the top chassis TC and the bottom chassis BC. The middle frame MF may be attached to the bottom chassis BC by a sixth adhesive layer AD6. In addition, a chassis protrusion of the top chassis TC may be inserted into a groove of the middle frame MF, so that the middle frame MF may be connected to the top chassis TC. Accordingly, the top chassis TC and the bottom chassis BC may be connected to each other.

In one or more embodiments, the electronic device ED may be manufactured by assembling the display device DD with the bracket BRK, the top chassis TC, the bottom chassis BC, and the middle frame MF. During this process, various impacts may be applied to the substrate SUB of the display panel DP. For example, when attaching the display device DD to the bracket BRK through the third adhesive layer AD3, or when attaching the top chassis TC to the display device DD through the fourth adhesive layer AD4, the edges of the display device DD may be pressed so that tensile stress may be concentrated on the edge portion EP of the substrate SUB. In addition, as the side surface of the display panel DP may contact an inner side wall of the bracket BRK, an impact may be applied to the substrate SUB. At this time, if there is no coating layer CL protecting the edge portion EP of the substrate SUB, the micro cracks primarily occurred in the edge portion EP of the substrate SUB as described above may further develop due to the tensile stress or the impact, so that the edge portion EP of the substrate SUB may be damaged. However, the display device DD according to embodiments may include the coating layer CL protecting the edge portion EP of the substrate SUB. The coating layer CL may cover the edge portion EP of the substrate SUB where the micro cracks occur. In addition, the stiffness of the edge portion EP of the substrate SUB may be improved by the coating layer CL having the thickness (e.g., predetermined thickness), and the neutral surface of the edge portion EP of the display device DD may be close to the surface of the substrate SUB where the micro cracks occur. Accordingly, it is possible to prevent or reduce development of the micro cracks from the edge portion EP of the substrate SUB otherwise caused due to the tensile stress or the impact generated when assembling the display device DD with the bracket BRK, the top chassis TC, the bottom chassis BC, and the middle frame MF. Thus, the reliability of the display device DD and the electronic device ED can be improved without expanding a bezel of the electronic device ED.

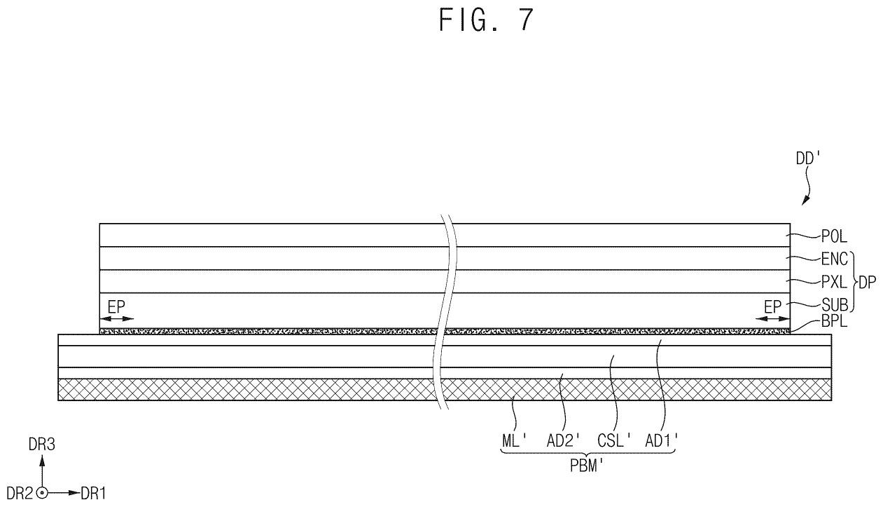

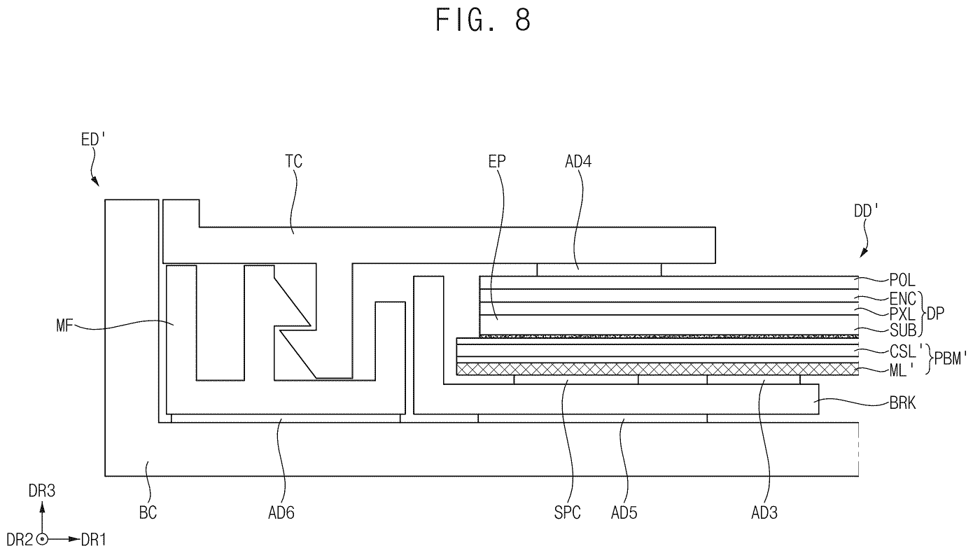

FIG. 7 is a cross-sectional view illustrating a display device according to one or more other embodiments. FIG. 8 is a diagram illustrating an electronic device including the display device of FIG. 7.

Referring to FIGS. 7 and 8, a display device DD′ according to one or more other embodiments may include a display panel DP, a polarizer POL, a black printing layer BPL, and a panel bottom member PBM′. The display device DD′ of FIGS. 7 and 8 may be substantially the same as or similar to the display device DD described with reference to FIGS. 1A to 5B, except that the coating layer CL is omitted, and except that an area of the panel bottom member PBM′ is greater than an area of the substrate SUB. Therefore, repeated descriptions may be omitted or simplified.

The area of the panel bottom member PBM′ may be greater than the area of the substrate SUB. The panel bottom member PBM′ may entirely cover the central portion and the edge portion EP of the substrate SUB. The substrate SUB may expose an edge portion of the panel bottom member PBM′. That is, in a plan view, the edges of the substrate SUB may be located inside the edges of the panel bottom member PBM′ (e.g., in plan view).

As illustrated in FIG. 8, the electronic device ED′ may be manufactured by assembling the display device DD′ with the bracket BRK, the top chassis TC, the bottom chassis BC, and the middle frame MF. At this time, as the panel bottom member PBM′ covers not only the central portion of the substrate SUB, but also covers the entire edge portion EP, the stiffness of the edge portion EP of the substrate SUB may be improved by the panel bottom member PBM′ having a thickness (e.g., predetermined thickness), and the neutral surface of the edge portion EP of the display device DD may be close to the surface of the substrate SUB where the micro cracks may occur. In addition, as the edges of the substrate SUB are located inside the edges of the panel bottom member PBM′ (e.g., in plan view), the side surface of the display panel DP may be separated from the inner side wall of the bracket BRK. Accordingly, it is possible to prevent or reduce development of the micro cracks from the edge portion EP of the substrate SUB due to the tensile stress or the impact generated when assembling the display device DD′ with the bracket BRK, the top chassis TC, the bottom chassis BC, and the middle frame MF. Thus, the reliability of the display device DD′ and the electronic device ED′ can be improved.

Although embodiments and implementations have been described herein, other embodiments and modifications will be apparent from this description.

Accordingly, the present disclosure is not limited to such embodiments, but rather to the broader scope of the appended claims and various obvious modifications and equivalent arrangements as would be apparent to a person of ordinary skill in the art.

What is claimed is:

1. A display device comprising:
a display panel comprising:
a substrate having a display area and a non-display area;
pixels in the display area above the substrate; and
an encapsulation layer covering the pixels;
a panel bottom member under the substrate, comprising a metal layer, and exposing an edge portion of the substrate; and
a coating layer under the edge portion of the substrate, and surrounding at least a portion of the panel bottom member.

2. The display device of claim 1, wherein the coating layer comprises a polymer resin.

3. The display device of claim 1, wherein the coating layer comprises a glass frit.

4. The display device of claim 1, wherein a thickness of the coating layer is less than or equal to a thickness of the panel bottom member.

5. The display device of claim 1, wherein the coating layer is spaced apart from the panel bottom member.

6. The display device of claim 1, wherein the coating layer adjoins the panel bottom member.

7. The display device of claim 1, wherein the edge portion of the substrate comprises a first edge portion extending in a first direction, a second edge portion parallel to the first edge portion, a third edge portion extending in a second direction crossing the first direction, and a fourth edge portion parallel to the third edge portion, and
wherein the display device further comprises:
a connection film comprising a first end portion connected on the first edge portion of the substrate, and a second end portion opposite the first end portion, the connection film being bent so that the second end portion is under the substrate; and
a circuit board under the substrate, and connected to the second end portion.

8. The display device of claim 7, wherein the coating layer is under the first edge portion, the second edge portion, the third edge portion, and the fourth edge portion of the substrate.

9. The display device of claim 8, wherein the coating layer has a ring shape in a plan view.

10. The display device of claim 7, wherein the coating layer is under the second edge portion, the third edge portion, and the fourth edge portion of the substrate, and is not under the first edge portion of the substrate.

11. The display device of claim 1, further comprising a black printing layer under the substrate,
wherein the panel bottom member and the coating layer are under the black printing layer.

12. The display device of claim 1, further comprising a polarizer above the display panel.

13. The display device of claim 1, wherein the panel bottom member further comprises an impact-absorbing layer between the substrate and the metal layer.

14. A display device comprising:
a display panel comprising:
a substrate having a display area and a non-display area;
pixels in the display area above the substrate;
an encapsulation layer covering the pixels; and
a panel bottom member under the substrate, comprising a metal layer, and having an area that is greater than an area of the substrate, the substrate exposing an edge portion of the panel bottom member.

15. The display device of claim 14, wherein edges of the substrate are inside edges of the panel bottom member in a plan view.

16. An electronic device comprising:
a display panel comprising:
a substrate having a display area and a non-display area;
pixels in the display area above the substrate;
an encapsulation layer covering the pixels;
a panel bottom member under the substrate to expose an edge portion of the substrate, and comprising a metal layer;
a coating layer under the edge portion of the substrate to surround at least a portion of the panel bottom member;
a bracket attached under the panel bottom member, and covering edges of the display panel and the panel bottom member;
a top chassis attached on the display panel; and
a bottom chassis attached under the bracket and connected to the top chassis.

17. The electronic device of claim 16, wherein the coating layer comprises a polymer resin.

18. The electronic device of claim 16, wherein the coating layer comprises a glass frit.

19. The electronic device of claim 16, wherein a thickness of the coating layer is less than or equal to a thickness of the panel bottom member.

20. The electronic device of claim 16, wherein the coating layer has a ring shape in a plan view.
